(19) United States
(12) Patent Application Publication
(10) Pub. No.: US 2026/0293024 A1
(43) Pub. Date: Sep. 24, 2026

(54) Tolerance Bracket with Increased Friction for Option Module

(71) Applicant: Dell Products L.P., Round Rock, TX (US)

(72) Inventors: Steven Michael Christensen, Austin, TX (US); Jacob H. Lavallo, Austin, TX (US)

(73) Assignee: Dell Products L.P., Round Rock, TX (US)

(21) Appl. No.: 19/085,939

(22) Filed: Mar. 20, 2025

(51) Int. Cl. H05K 7/14; G06F 1/18

(52) U.S. Cl. CPC H05K 7/1422; G06F 1/183

(57) ABSTRACT

An option module for an information handling system (IHS) is disclosed. The option module includes a circuit board, a module bracket with a fastener opening, and a tolerance bracket featuring a slotted opening. A module fastener passes through the slotted opening into the fastener opening, allowing the tolerance bracket to adjust relative to the module bracket when loosened and lock in place when tightened. Fabric sheets are used to increase friction between the brackets, enhancing clamping performance with lower torque.

### BACKGROUND

Information Handling Systems (IHS) generally process, compile, store, and/or communicate information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use. In addition, information handling systems may include a variety of hardware and software components that may be configured to process, store, and communicate information and may include one or more computer systems, data storage systems, and networking systems.

IHSs are generally built from a wide variety of components. Selecting components to include within an information handling system helps end users target the capabilities of the information handling system for planned tasks. Typically, an information handling system has a motherboard that couples to a chassis to support communication between information handling system components. A typical motherboard is a printed circuit board (PCB) that has one or more central processing unit (CPU) sockets to accept one or more CPUs for executing instructions. The CPU sockets interface through the motherboard with memory sockets that hold memory for storing information in support of executing instructions, such as DIMM sockets that hold DRAM modules. The motherboard can interface with a variety of other components, such as an embedded controller, a network interface module, a graphics processor and other types of chipset components supported by the motherboard that perform processing functions. Generally, components interface through the motherboard using standardized communications links, such as a PCI or PCIe bus.

In some instances, processing functions are performed by components located off the motherboard, such as components supported by daughter boards or option modules. Option modules typically include a PCB with function-specific components, such as graphics components or network communication components. Option modules generally include an interface that provides communication with the motherboard through the motherboard's communications link, such as a PCI or PCIe bus. By distributing functions to option modules, an IHS provides end users with greater flexibility for the selection of components. For example, a graphics subsystem built on an option module will typically provide more effective graphics processing than the graphics components included with a chipset coupled to a motherboard. As another example, a server adjusts to interface with local area networks and/or storage networks by inserting appropriate option modules for the desired interfaces. One difficulty with the use of option modules is ensuring that the option modules will securely couple to the motherboard with proper electrical interfaces and without inducing forces on connections or interfaces to the motherboard.

### SUMMARY

In one embodiment, an option module comprises a circuit board, a module bracket attached to the circuit board, a first fabric attached to an outside surface of the module bracket, a tolerance bracket surrounding at least a portion of the module bracket, a second fabric attached to an inside surface of the tolerance bracket and positioned to contact the first fabric sheet, and a module fastener configured to exert a clamping force to the module bracket and the option bracket. The module bracket is nested within the tolerance bracket. The option module further includes a fastener opening in the module bracket, a slotted opening in the tolerance bracket, wherein the module fastener extends through the slotted opening and through the fastener opening.

The tolerance bracket is configured to move relative to the module bracket when the module fastener is in a loosened condition. The first fabric sheet and second fabric sheet are configured to create a friction between the tolerance bracket and the module bracket when the module fastener is in a tightened condition. In one example, the friction requires at least 80 N to create 0.5 mm displacement between the tolerance bracket and the module bracket with the module fastener tightened to 1.75 in-lb. The material of the first fabric sheet may be the same as the material of the second fabric sheet.

The embodiments are directed to installing an option module within an information handling system chassis. The option module comprises: a circuit board, a module bracket attached to the circuit board, a tolerance bracket surrounding at least a portion of the module bracket, and fabric sheets between the module bracket and the tolerance bracket to increase the friction between the brackets. The module bracket has a fastener opening, and the tolerance bracket has a slotted opening. A module fastener extends through the slotted opening and into the fastener opening. The tolerance bracket can move relative to the module bracket when the module fastener is in a loosened condition; however, the tolerance bracket is locked in place relative to the module bracket when the module fastener is in a tightened condition.

The option module further includes a chassis engagement device on the tolerance bracket. The chassis engagement device may comprise at least one hook configured to engage a bracket on a chassis wall. The at least one hook may be a vertical tab extending upward from the tolerance bracket. Alternatively, the chassis engagement device may comprise at least one tab extending vertically from an end of the tolerance bracket, wherein the at least one tab is configured to pass through an opening in a chassis wall and to engage the outside of the chassis wall instead of a mounting bracket.

The module further includes a positioning tab attached to the tolerance bracket. The positioning tab is configured to prevent the tab from passing through an opening in a chassis wall. The positioning tab may comprise a tab extending laterally from an end of the tolerance bracket. In some embodiments, the positioning tab may include a fastener hole configured to receive a chassis fastener to attach the tolerance bracket to a chassis wall.

These and other features will be more clearly understood from the following detailed description taken in conjunction with the accompanying drawings and claims.

### BRIEF DESCRIPTION OF THE DRAWINGS

Having thus described the invention in general terms, reference will now be made to the accompanying drawings, which are not necessarily drawn to scale, and wherein:

FIGS. 1A and 1B are partially exploded views of an option module according to an example embodiment.

FIG. 2 illustrates a portion of an IHS chassis.

FIGS. 3A-3C illustrate a cross section view of an option module being installed in a chassis.

FIG. 4 is an isometric view of the inside of a chassis showing an option module installed.

FIG. 5 is an isometric view of the outside of a chassis showing the option module installed.

FIG. 6 is a graph illustrating the force-displacement plot of sample fabrics tested in an option module.

### DETAILED DESCRIPTION

The invention now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. One skilled in the art may be able to use the various embodiments of the invention.

Embodiments disclosed herein provide an architecture that reduces shear strain on a board-to-board (BTB) connection between an option module and a motherboard in an IHS chassis. The chassis may have different form factors, such as Desktop (DT), Mini Tower (MT), Small Form Factor (SFF), etc. The option module is used to incorporate optional features into the IHS chassis. This may include, for example, port module cards that add customer-selected ports such as HDMI, USB, Ethernet, or other ports or external connections. Typically, such option modules are mounted within the chassis and expose a desired port connection through an opening in a chassis wall (e.g., a USB port on the back wall of a chassis). Existing option modules are mechanically connected to the chassis wall using screws, for example, that hold the option modules in place. The screws used in prior option modules provide a rigid connection to the chassis wall that absorbs the strain induced by plugging/unplugging connectors to the port. As a result, the option modules are required to have two rigid connections. The first rigid connection is at the rear wall (e.g., where the option module functionality is exposed to a user), and the second rigid connection is at the connector interface (e.g., the connection between the option module and a motherboard). These rigid connections cause a tolerance problem. For example, if the distance between the chassis rear wall and the motherboard connector differs from the distance designed into the option module, then sheer forces will be applied to the option module-motherboard connection (e.g., a board-to-board connector) once the option module is installed. This can result in damage to the connector, which will impact option module functionality and operation. Legacy option modules were connected to the motherboard via a cable and, therefore, only had a single rigid connection at the rear wall.

Existing option modules use cable connections between the option module cards and the motherboard. These cables provide flexibility. Once the prior option module was attached to the chassis wall, a cable could connect between any area on the module card to an area on the motherboard. However, a BTB connection has several advantages over a cable connection, including increased signal integrity, higher density of connections within a smaller space, improved electrical performance due to shorter signal paths, greater mechanical stability, and easier assembly in compact systems by eliminating the need for separate cables and allowing for stacking of circuit boards directly on top of each other. BTB connections are limited by requiring a precise alignment to avoid strain on the connectors. The architecture disclosed herein provides a tolerance bracket on the option module that allows for proper connector alignment without inducing sheer strain on a BTB connector.

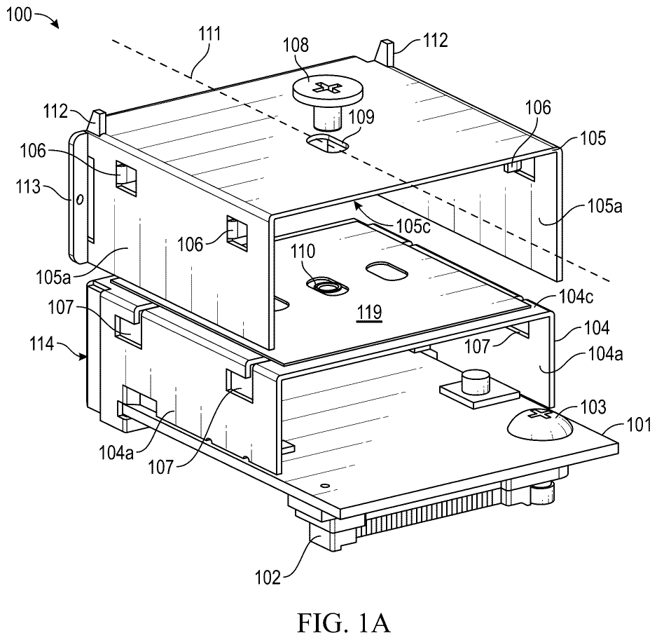

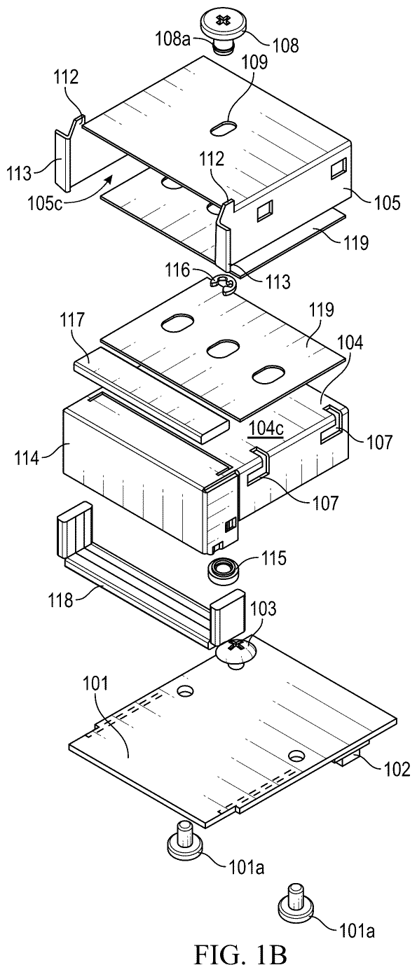

FIGS. 1A and 1B are exploded views of an option module 100 according to an example embodiment. Printed circuit board assembly (PCBA) 101 contains all the electronic components (not shown) needed to make the option module 100 function as required. These components may include, for example, physical ports and connectors, controller chips, integrated circuits (ICs), data and power traces, and power regulation devices. A connector 102 mounted on the bottom surface of PCBA 101 is configured to mate with a corresponding connector on a motherboard. Connector 102 may be a male or female connector with any number and pattern of pins as appropriate to attach to the connector on the motherboard. A screw 103 is positioned through PCBA 101 and connector 102. Screw 103 is configured to engage a threaded hole in the motherboard connector. When option module 100 is mounted within a chassis, screw 103 is tightened to lock the BTB connector ends together.

The components on PCBA 101 are protected by an option module bracket 104 that is attached to PCBA 101 by fasteners 101a. A tolerance bracket 105 is configured to fit over and around the sides of option module bracket 104. In the illustrated embodiment, tabs 106 are formed in the sidewalls 105a of tolerance bracket 105. Tabs 106 are bent inwards and are configured to engage slots 107 formed in the sidewalls 104a of option module bracket 104. Tabs 106 are lowered into slots 107 and are then moved forward, which secures tolerance bracket 105 vertically to option module bracket 104.

A fastener 108 passes through a slot 109 in tolerance bracket 105 and into a hole 110 in option module bracket 104. Screw 108 engages either threads in hole 110 or a nut 115 (FIG. 1B) below hole 110. A C-clip 116 is adapted to engage groove 108a on fastener 108 and is used to retain screw when loose. When screw 108 is loose, tolerance bracket 105 can move longitudinally relative to option module bracket 104 along axis 111. When tolerance bracket 105 is in a desired position relative to option module bracket 104, fastener 108 is tightened to lock the brackets 104, 105 together.

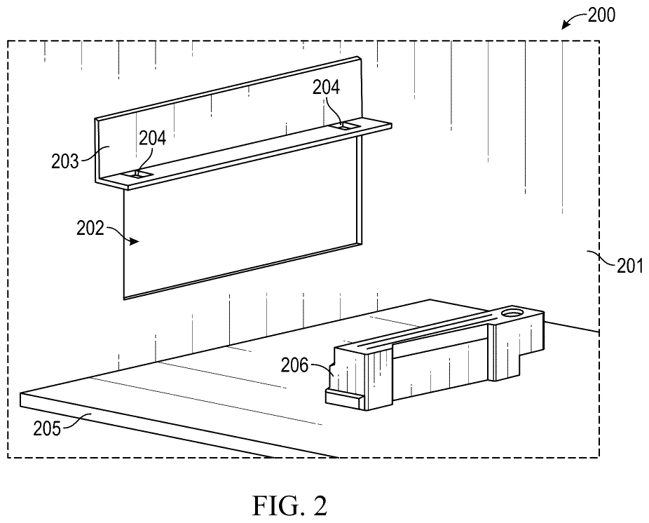

Tolerance bracket 105 has hooks 112 that are configured to engage a mounting bracket (e.g., bracket 203, FIG. 2) on a chassis. Tabs 113 on tolerance bracket 105 are positioned to rest against the chassis wall (e.g., wall 201, FIG. 2) when the option module 100 is installed. Typically, option module 100 has a panel side or face 114 that is exposed to users through the chassis wall.

In some embodiments, electromagnetic interference (EMI) foam 117, 118 may be used to protect components on PCBA 101 from being disrupted by external electromagnetic signals as well as preventing signals generated on the option module 100 from interfering with surrounding components.

FIG. 2 illustrates a portion of an IHS chassis 200 having a wall 201, such as a rear wall of the chassis. An opening 202 is formed in wall 201. Opening 202 is configured to receive the panel side 114 of option module 100 (FIG. 1). A mounting bracket 203 is attached to wall 201 above the opening 202. Mounting bracket 203 has holes 204 that are configured to receive the hooks 112 on option module 100. Chassis 200 further includes a motherboard 205 and a connector 206. When an option module is installed on wall 201, the option module connector 102 attaches to motherboard connector 206.

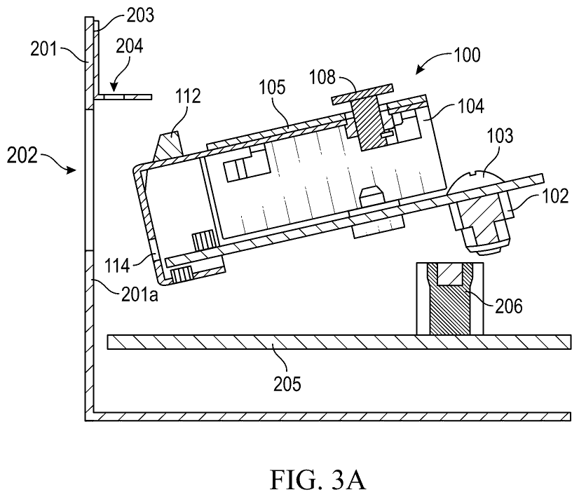

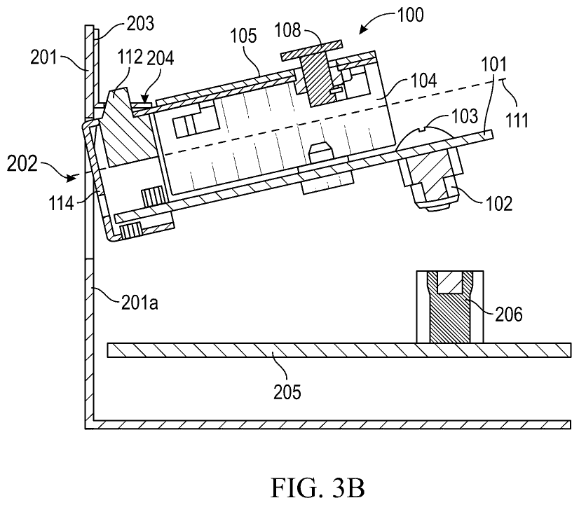

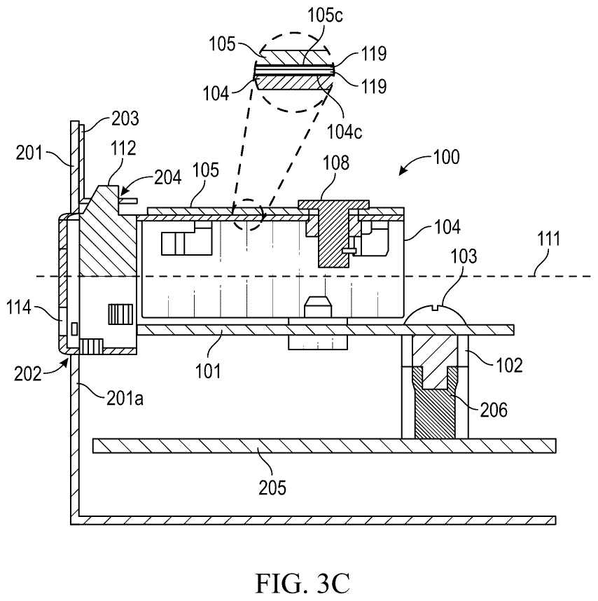

FIGS. 3A-3C illustrate a cross section view of an option module (e.g., option module 100, FIG. 1) being installed in a chassis (e.g., chassis 200, FIG. 2) according to one embodiment. In FIG. 3A, the option module 100 is angled toward opening 202 in wall 201. The panel side 114 of option module 100 is passed through the opening 202. In FIG. 3B, option module 100 is lifted upward so that hooks 112 engage holes 204 in mounting bracket 203. During the initial installation steps (e.g., FIGS. 3A, 3B), fastener 108 is loose and tolerance bracket 105 is able to move longitudinally relative to option module bracket 104 along axis 111.

In FIG. 3C, option module 100 is rotated so that connector 102 attaches to motherboard connector 206. Option module bracket 104 moves along axis 111 within tolerance bracket 105 as necessary for connector 102 to align and mate with connector 206 without introducing any sheer forces on the connectors.

The ability of option module bracket 104 to move within tolerance bracket 105 during installation provides an auto-adjusting tolerance compensation for variations between different chassis designs. Bracket 104 is rigidly attached to PCBA 101, and tolerance bracket 105 is rigidly attached to a chassis wall. In different chassis models, the thickness of wall 201 may vary. The tolerance bracket architecture disclosed herein does not rely on knowing the wall thickness, but instead only requires that holes 204 on bracket 203 are positioned accurately for hooks 112 in order to secure the tolerance bracket 105 to wall 201.

Additionally, manufacturing tolerances may cause the distance from wall 201 to motherboard connector 206 to vary across different units. Since the option module is installed with screw 108 in a loose configuration, the option module bracket 104 and PCBA 101 are able to freely slide back-and-forth within tolerance bracket 105 relative to chassis wall 201. This allows connector 102 to properly align with 206 without inducing sheer forces caused by tolerance stack-up between mated connectors 102/206 and walls 114/201. Once connectors 102, 206 are attached, screw 103 may be tightened to lock the connectors together.

The amount of free play between option module bracket 104 and tolerance bracket 105 can easily be modified by increasing the length of slot 109 and slot 107. In an example embodiment, slot 109 may allow for +/−1.0 mm of movement between option module bracket 104 and tolerance bracket 105. After the connectors 102, 206 are attached and screw 103 is tightened, fastener 108 can be tightened to lock the option module bracket 104 and tolerance bracket 105 together and prevent additional movement (i.e., fastener 108 clamps option module bracket 104 and tolerance bracket 105 together).

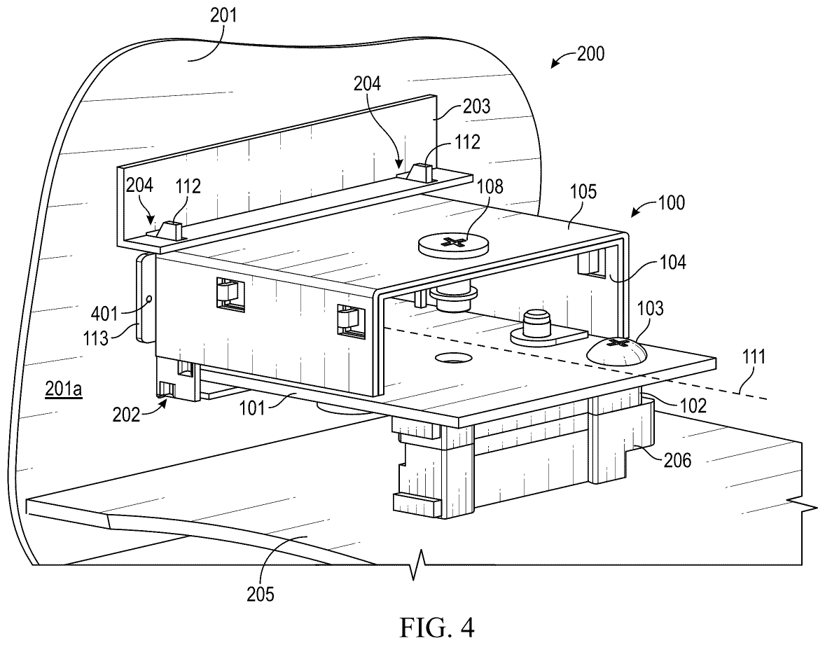

FIG. 4 is an isometric view of the inside of chassis 200 showing the option module 100 installed. Hooks 112 are engage in holes 204, which prevents any further movement of tolerance bracket 105 away from wall 201. When option module 100 is in position, tabs 113 are flush against the inside surface 201a of wall 201, which prevents any further movement of tolerance bracket 105 toward wall 201. Accordingly, between hooks 112 and tabs 113, tolerance bracket 104 is fully constrained along axis 111. Option module bracket 104 is constrained along axis 111 after connector 102 is attached to connector 206. Once option module bracket 104 and tolerance bracket 105 are in place, tightened fastener 108 prevents any further movement of the components.

In some configurations, option module 100 may need to be grounded to chassis 200 to prevent EMI. FIG. 4 illustrates an EMI grounding point 401 on tab 113. Grounding point 401 may be, for example, a dimple on tab 113 that ensure metal-to-metal contact between option module 100 and wall 201.

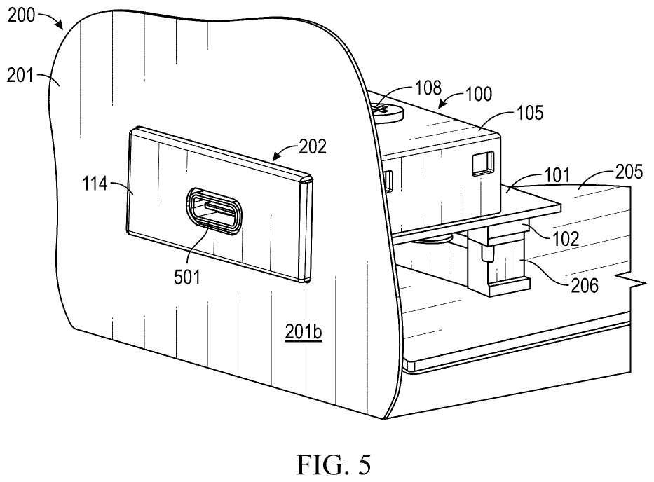

FIG. 5 is an isometric view of the outside of chassis 200 showing the option module 100 installed. Panel side 114 of option module 100 fits in opening 202 and may be flush with exterior surface 201b of wall 201 or may extend beyond surface 201b. Depending upon the components in option module 100, panel side 114 may provide a port 501 or other user interface, such as lights, switches, buttons, displays, speakers, etc.

Prior option modules were cabled and were not mechanically connected to the motherboard board via a BTB connector. Option module 100 as disclosed herein utilizes a board-to-board mezzanine connection 102/206 to enable more features and improve manufacturability and serviceability. However, the board-to-board connection also introduces a mechanical tolerance loop from the motherboard connector 102/206 to option module bracket 104 to chassis wall 201 to option module connector 501. The tolerance is different for every chassis type, for example, the tolerance may be +/−0.7 mm for a micro form factor chassis and somewhat less for small form factor and mini tower chassis. For an option module without tolerance bracket 105, manufacturing/installation tolerances in combination with high plug-in forces at port 501 could damage the BTB connectors 102/206.

The mechanical design of option module 100 provides the sliding tolerance bracket 105 to compensate for manufacturing variations. Tolerance bracket 105 automatically adjusts to chassis tolerances so that BTB connectors 102/206 align properly. Tolerance bracket 105 couples option module 100 to chassis rear wall 201 to help absorb loads exerted on the face 114 of the module (e.g., insertion force loads when plugging in to port 501). In an example use case, the module face 114/port 501 should be able to experience up to 100 N of push or pull force without damaging BTB connector 102/206. This would require a minimum torque of 4 in-lb (i.e., clamping force) when tightening fastener 108 during installation of option module 100. If a lower torque is used, then option module bracket 104 may slide within tolerance bracket 105 (which is locked onto chassis wall 201) under high insertion forces and transfer the forces directly to the BTB connector, which negates the functional intent of option module 100.

Practical issues arises when requiring specific torques for bracket fastener 108, such as the availability of a manufacturing tool (e.g., a torque driver) that can generate a specific torque. In some manufacturing environments, the available torque drivers may generate excessive torque (e.g., 6 in-lb) or insufficient torque (e.g., 1.75 in-lb) relative to the target torque. In the case of excessive torque, applying too much torque on fastener 108 may damage or crush brackets 104, 105 (i.e., over-clamping) or may break fastener 108 (i.e., over-torquing). In the case of a tool providing insufficient torque, this results in an insufficient clamping force that would not prevent option module bracket 104 from sliding within tolerance bracket 105.

Because excess torque would damage the option module 100, the only useable option to tighten fastener 108 during installation may be a torque driver that generates lower torque, which would provide less than desired clamping force. However, a weak clamping force applied to option module bracket 104 and tolerance bracket 105 may be overcome by increasing the friction between the brackets. Typically, option module bracket 104 and tolerance bracket 105 are made of metal with a relatively low friction coefficient where the brackets touch. The friction coefficient between option module bracket 104 and tolerance bracket 105 may be increased by adding a very thin fabric material between the brackets.

Referring to FIGS. 1A and 1B, fabric 119 is attached to the underside 105c of tolerance bracket 105 and to the top surface 104c of option bracket 104. Fabric 119 may be attached to surfaces 105c and 104c using a glue or adhesive, such as a “self-stick” tape applied to the back of fabrics 119. When option module 100 is assembled, the two fabric 119 sheet will contact each other. Fibers in the fabric sheets 119 will interlock when the two pieces of material contact each other. This creates a higher friction coefficient than bare metal contact. By increasing the friction coefficient between tolerance bracket 105 and option module bracket 104, the clamping performance is increased (compared to bare metal clamping) with the same torque applied to fastener 108. This allows a manufacturer to use a lower torque installation tool and/or allows service personnel or end-user customers to tightened fastener 108 to a lower torque than required for bare metal contact.

In various embodiments, fabric 119 may be a textured craft paper, cold press paper, felt finish paper, or rough paper. In one configuration, a commercially available thin, self-stick liquid protection fabric, such as a non-woven polymer layer, may be used as fabric 119.

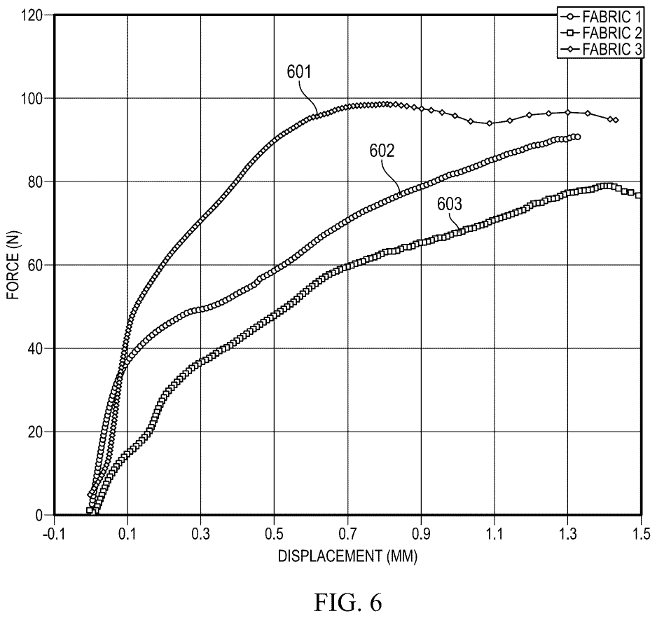

FIG. 6 is a graph illustrating the force-displacement plot of sample fabrics tested in an option module 100 a 1.75 in-lb torque applied to fastener 108. As illustrated, a fabric 119 having characteristics of Fabric 1 (plot 601) is preferred over gripping material 2 (plot 602) and gripping material 3 (plot 603) due to the higher amount of force required to induce displacement of the option module bracket 104 relative to tolerance bracket 105. Research testing included a fabric material (Fabric 1) that was not specifically designed for a nonslip application and gripping materials, such as sticky rubber sheets, that were designed for this type of application. The fabric material with fibers that interlock when the two pieces of fabric contact each other outperformed the other materials when used in the application described above.

In an example embodiment, a module for an IHS chassis comprises a circuit board, a module bracket attached to the circuit board, a first fabric attached to an outside surface of the module bracket, a tolerance bracket surrounding at least a portion of the module bracket, a second fabric attached to an inside surface of the tolerance bracket and positioned to contact the first fabric sheet, and a module fastener configured to exert a clamping force to the module bracket and the option bracket. The module further comprises a fastener opening in the module bracket, a slotted opening in the tolerance bracket, and the module fastener extending through the slotted opening and through the fastener opening.

The module bracket is nested within the tolerance bracket. The tolerance bracket is configured to move relative to the module bracket when the module fastener is in a loosened condition. The first fabric sheet and second fabric sheet are configured to create a friction between the tolerance bracket and the module bracket when the module fastener is in a tightened condition. The friction requires at least 80-100 N to create 0.5 mm displacement between the tolerance bracket and the module bracket with the module fastener tightened to 1.75 in-lb.

The material of the first fabric sheet is the same as a material of the second fabric sheet in one configuration. In other arrangements, the first fabric sheet and the second fabric sheet each comprise different materials.

The fastener opening may be threaded, and the module fastener is configured to engage threads within the fastener opening. Alternatively, the module may include a fastener nut, where the module fastener is threaded and configured to engage the fastener nut.

The fastener opening may be located in a top surface or in a side surface of the module bracket, and the slotted opening is located in a corresponding top or side surface of the tolerance bracket.

The module may further include a chassis engagement device on the tolerance bracket. The chassis engagement device may be at least one hook configured to engage a bracket on a chassis wall. The at least one hook may include a vertical tab extending away from the tolerance bracket. Alternatively, the chassis engagement device may include at least one tab extending vertically from an end of the tolerance bracket.

A positioning tab may be attached to the tolerance bracket. The positioning tab is configured to prevent the module from passing through an opening in a chassis wall. The positioning tab may include a tab extending laterally from an end of the tolerance bracket.

In an example arrangement, an information handling system comprises a chassis having a chassis wall, and an option module attached to the chassis wall. The option module comprises a circuit board, a module bracket attached to the circuit board, a first fabric attached to an outside surface of the module bracket, a tolerance bracket surrounding at least a portion of the module bracket, a second fabric attached to an inside surface of the tolerance bracket and positioned to contact the first fabric sheet, and a module fastener configured to exert a clamping force to the module bracket and the option bracket.

The tolerance bracket includes at least one hook on. The at least one hook is configured to engage a bracket on the chassis wall. A positioning tab is attached to the tolerance bracket. The positioning tab is configured to prevent the module from passing through an opening in the chassis wall.

The module bracket is nested within the tolerance bracket, and the first fabric sheet and second fabric sheet are configured to create a friction between the tolerance bracket and the module bracket when the module fastener is in a tightened condition.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated that the conception and specific embodiment disclosed may be readily utilized as a basis for modifying or designing other structures for carrying out the same purposes of the present invention. It should also be realized that such equivalent constructions do not depart from the invention set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

What is claimed is:

1. A module, comprising:
a circuit board;
a module bracket attached to the circuit board;
a first fabric attached to an outside surface of the module bracket;
a tolerance bracket surrounding at least a portion of the module bracket;
a second fabric attached to an inside surface of the tolerance bracket and positioned to contact the first fabric sheet; and
a module fastener configured to exert a clamping force to the module bracket and the option bracket.

2. The module of claim 1, further comprising:
a fastener opening in the module bracket;
a slotted opening in the tolerance bracket; and
the module fastener extending through the slotted opening and through the fastener opening.

3. The module of claim 1, wherein the module bracket is nested within the tolerance bracket.

4. The module of claim 1, wherein the tolerance bracket is configured to move relative to the module bracket when the module fastener is in a loosened condition.

5. The module of claim 1, wherein the first fabric sheet and second fabric sheet are configured to create a friction between the tolerance bracket and the module bracket when the module fastener is in a tightened condition.

6. The module of claim 5, wherein the friction requires at least 100 N to create 0.5 mm displacement between the tolerance bracket and the module bracket with the module fastener tightened to 1.75 in-lb.

7. The module of claim 5, wherein the friction requires at least 80 N to create 0.5 mm displacement between the tolerance bracket and the module bracket with the module fastener tightened to 1.75 in-lb.

8. The module of claim 1, wherein a material of the first fabric sheet is the same as a material of the second fabric sheet.

9. The module of claim 1, wherein the fastener opening is threaded and the module fastener is configured to engage threads in the fastener opening.

10. The module of claim 1, further comprising:
a fastener nut, wherein the module fastener is threaded and configured to engage the fastener nut.

11. The module of claim 1, wherein the fastener opening is located in a side surface of the module bracket, and wherein the slotted opening is located in a side surface of the tolerance bracket.

12. The module of claim 1, further comprising:
a chassis engagement device on the tolerance bracket.

13. The module of claim 12, wherein the chassis engagement device comprises:
at least one hook configured to engage a bracket on a chassis wall.

14. The module of claim 13, wherein the at least one hook comprises a vertical tab extending away from the tolerance bracket.

15. The module of claim 12, wherein the chassis engagement device comprises:
at least one tab extending vertically from an end of the tolerance bracket.

16. The module of claim 1, further comprising:
a positioning tab attached to the tolerance bracket, wherein the positioning tab is configured to prevent the module from passing through an opening in a chassis wall.

17. The module of claim 14, wherein the positioning tab comprises:
a tab extending laterally from an end of the tolerance bracket.

18. An information handling system, comprising:
a chassis having a chassis wall; and
an option module attached to the chassis wall, the option module comprising:
a circuit board;
a module bracket attached to the circuit board;
a first fabric attached to an outside surface of the module bracket;
a tolerance bracket surrounding at least a portion of the module bracket;
a second fabric attached to an inside surface of the tolerance bracket and positioned to contact the first fabric sheet; and
a module fastener configured to exert a clamping force to the module bracket and the option bracket.

19. The information handling system of claim 18, further comprising:
at least one hook on the tolerance bracket, the at least one hook configured to engage a bracket on the chassis wall; and
a positioning tab attached to the tolerance bracket, wherein the positioning tab is configured to prevent the module from passing through an opening in the chassis wall.

20. The information handling system of claim 18, wherein the module bracket is nested within the tolerance bracket, and
wherein the first fabric sheet and second fabric sheet are configured to create a friction between the tolerance bracket and the module bracket when the module fastener is in a tightened condition.
